(19) United States
(12) Patent Application Publication
(10) Pub. No.: US 2022/0193815 A1
(43) Pub. Date: Jun. 23, 2022

(54) BONDING ARRANGEMENT AND BONDING TOOL

(71) Applicant: Hesse GmbH, Paderborn (DE)

(72) Inventors: Andreas UNGER, Verl (DE); Michael BROEKELMANN, Delbrueck (DE); Matthias HUNSTIG, Paderborn (DE); Hans-Juergen HESSE, Paderborn (DE)

(73) Assignee: Hesse GmbH, Paderborn (DE)

(21) Appl. No.: 17/691,801

(22) Filed: Mar. 10, 2022

Related U.S. Application Data
(63) Continuation of application No. PCT/DE2020/100785, filed on Sep. 8, 2020.

(30) Foreign Application Priority Data
Sep. 11, 2019 (DE) 10 2019 124 334.3

(51) Int. Cl. B23K 20/10; B23K 20/00; B23K 26/20

(52) U.S. Cl. CPC B23K 20/106; B23K 26/20; B23K 20/004

(57) ABSTRACT

A bonding arrangement comprising a bonding tool, having a tool shank which is designed to extend in a longitudinal direction of the tool, and a tool tip which connects to the tool shank. A first end side of the bonding tool is provided on the tool tip, which is designed to come into contact with a connection part. A second end side of the bonding tool is provided on the tool shank. The bonding tool has a casing surface connecting the first end side and the second end side, said bonding arrangement comprising a laser generator for providing a laser beam and comprising a light guide designed to guide the laser beam to the bonding tool. A functional recess is formed on the bonding tool on the casing side and the light guide is associated with the bonding too on the casing side from the outside and at a distance.

This nonprovisional application is a continuation of International Application No. PCT/DE2020/100785, which was filed on Sep. 8, 2020, and which claims priority to German Patent Application No. 10 2019 124 334.3, which was filed in Germany on Sep. 11, 2019, and which are both herein incorporated by reference.

### BACKGROUND OF THE INVENTION

Field of the Invention

The present invention relates to a bonding arrangement and a bonding tool for laser-supported bonding. Furthermore, the invention relates to the use of the bonding arrangement or the bonding tool for laser-supported ultrasonic bonding.

Description of the Background Art

From the applicant's post-published German patent application 10 2018 120 822.7, which corresponds to US 2021/0178515, which is incorporated herein by reference, a bonding arrangement and a bonding tool is illustrated, having a functional recess provided on the lateral surface of the bonding tool. Here, in addition, a longitudinal recess is provided on the bonding tool, which extends from an end side of the bonding tool along a tool shank to the functional recess. In the longitudinal recess, the light guide is provided, which serves to conduct the laser beam to the functional recess. The laser beam then impinges on the bonding tool in the area of the functional recess and heats it.

### SUMMARY OF THE INVENTION

It is therefore an object of the present invention to provide an improved bonding arrangement with regard to the assembly capability, and an adapted bonding tool for laser-supported bonding.

Accordingly, in an exemplary embodiment, the bonding arrangement comprises a bonding tool having a tool shank which is designed to extend in a longitudinal direction of the tool, and having a tool tip which connects to the tool shank, wherein a first end side of the bonding tool is provided on the tool tip, which is designed to come into contact with a connection part, wherein a second end side of the bonding tool is provided on the tool shank and wherein the bonding tool has a casing surface connecting the first end side and the second end side. Furthermore, the bonding arrangement comprises a laser generator for providing a laser beam and comprises a light guide designed to guide the laser beam to the bonding tool. A functional recess is formed on the bonding tool on the casing side. The light guide is associated with the bonding tool on the casing side from the outside and at a distance such that the laser beam coupled out via an end side of the light guide facing the functional recess impinges on the bonding tool in the functional recess.

An advantage of the invention is that the light guide associated with the bonding tool from the outside can be easily and precisely mounted and positioned. In addition, the bonding tool can be easily replaced. The correct positioning of bonding tool or functional recess on the one hand and light guide on the other hand can, for example, be manually checked.

Above all, by providing the functional recess, the heat flow from the tool tip towards the tool shank is reduced. The heat flow is proportional to a cross-sectional area of the bonding tool, and, because of the functional recess, the cross-sectional area is reduced as compared to an otherwise geometrically identical bonding tool without a functional recess. Hence, heating of the tool tip is improved and accelerated since less heat enters the tool shank, and efficiency is increased. In addition, less material has to be heated because of the material recess.

The functional recess is provided on a casing surface of a tool that connects the first end side of the bonding tool with the second end side. The first end side of the bonding tool is usually located opposite the second end side of the bonding tool. On the first end side, a bond contact surface is provided, which serves and is designed to come into contact with a connection part when establishing the bond connection. The connection part is then pressed against a substrate or a functional component in order to establish the bond connection with the bonding tool. For example, on the underside of the bonding tool, a V-shaped receiving slot, which extends transversely to the longitudinal direction of the tool, is provided for centering a bond wire which forms the connection part.

The tool casing surface of the bonding tool extends in the area of the tool shank and the tool tip. A transition from the tool shank of the bonding tool to the tool tip is defined, for example, by a change in the outer geometry of the bonding tool. In a bonding tool for ultrasonic wire bonding, for example, the bonding tool tapers, for example, in a wedge-shaped manner in the area of the tool tip towards the underside of the bonding tool.

As a light guide for the laser beam, for example, a glass fiber or a glass fiber bundle may be provided. For example, a plastic or a glass rod may be provided as a light guide. For example, a tube or a flexible hose can serve as a light guide for guiding the laser beam.

The functional recess can be formed according to the type of beam trap such that at least one boundary surface of the functional recess is designed as a deflection surface and/or absorption surface for the laser. On the one hand, the deflection surface of the functional recess is arranged such that a laser beam guided in the light guide impinges on the deflection surface after exiting the light guide and is then deflected on it in such a way that a reflection in the direction of the light guide is avoided. In this respect, the deflection surface of the functional recess has an angle of attack deviating from 0° or 90° to a direction of incidence of the laser beam or is curved. For example, the functional recess can taper wedge-shaped in the direction of the first end side for the implementation of the beam trap function. Advantageously, by providing the deflection surface, it is avoided that the laser beam is reflected in the direction of the light guide and damages it. Finally, by adding the boundary surface, the surface heated by the laser beam can be enlarged with the result that the tool tip is heated more homogeneously or damage to the tool due to unacceptably high local heating is counteracted. Likewise, the enlargement of the heated surface reduces the intensity and subsequently the number of particles released when heating the tool tip, which are thrown back in the direction of the light guide and/or can contaminate the substrate or the functional component.

The functional recess can be in any case partially, and preferably completely, formed on the tool tip. Advantageously, this arrangement facilitates the local heating of the tool tip, or it counteracts undesirable heating of the tool shank. By locally heating the tool tip, process times can be reduced and/or bondability improved.

The functional recess can be prepared, for example, by wire EDM and/or die-sinking EDM. In addition, the functional recess is subsequently formed on the casing side of an existing bonding tool. For example, the functional recess can be formed already during the production of the bonding tool. The bonding tool having the functional recess can, for example, be produced aby primary forming.

The laser beam can be totally reflected on the casing side of the light guide. Optionally, the light guide can comprise a reflection coating for the realization of total reflection, at least on sections of the casing side. As a result, the laser beam can be guided particularly effectively in the light guide. The reflection coating may, for example, be designed in such a way that, in particular, radiation having the specific wavelength such as the one used by the laser used to provide the laser beam, is reflected by the light guide with low loss and passed through the light guide.

A width of the functional recess may always be less than two thirds and preferably less than one half of a corresponding outer width of the bonding tool. In this case, the width of the functional recess and the corresponding width of the bonding tool—in relation to the longitudinal direction of the tool—are measured transversely to the longitudinal direction of the tool in the same location on the bonding tool. Advantageously, by limiting the width of the functional recess, sufficient mechanical stability of the bonding tool can always be ensured. At the same time, it may be ensured that especially in ultrasonic bonding, the ultrasonic vibrations are effectively transmitted or that a reproducible bending and/or longitudinal oscillation forms in the bonding tool.

The functional recess can be formed as a through recess. In this respect, the functional recess provides two openings on the casing side, which preferably lie opposite each other. Advantageously, by forming the functional recess as a through recess, the functional recess can be particularly easily produced. At the same time, the continuously formed functional recess can serve to conduct compressed air or to provide an air flow, so that if necessary, the tool tip is cooled and, in particular, the particles, which were released when the tool tip was heated, are conducted laterally from the bonding tool. In addition, the formation of a through recess, in particular using wire EDM, is advantageous.

The functional recess may be pocket-shaped. This can increase the stability of the bonding tool. In addition, the encapsulation of the laser beam or a scattering of the laser beam and impingement of the laser beam on surfaces outside the bonding tool is better counteracted by the trough shape since the laser beams cannot escape through the closed side of the trough. For example, the pocket or trough-shaped recess can be produced by die-sinking EDM.

The bonding tool can comprise a tool shank which extends in a longitudinal direction of the tool, and a tool tip which connects to the tool shank. On the tool tip, a first end side of the bonding tool is provided, which is designed to come into contact with a connection part. A second end side with a closed surface is provided on the tool shank. In addition, the bonding tool has a casing surface connecting the first end side and the second end side, wherein a functional recess is formed on the bonding tool on the casing side.

The second end side of the bonding tool can have a closed surface if no recess is provided on it. In particular, the bonding tool of the invention does not provide a longitudinal recess extending from the second end side to the functional recess.

It may be provided that the bonding tool is symmetrically formed in relation to a median longitudinal plane. This results in particularly advantageous vibration properties for the bonding tool, so that the symmetrical bonding tool is particularly suitable for ultrasonic bonding and there in particular for use in ultrasonic wire bonding.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a front view of a bonding tool according to the invention having a functional recess formed on the casing side, which is designed as a through recess in the area of the tool tip of the bonding tool, in a first embodiment,

FIG. 2 is a detail X of the bonding tool according to FIG. 1 in an enlarged representation,

FIG. 3 is a longitudinal side view of the bonding tool according to FIG. 1,

FIG. 4 is a view of the underside of the bonding tool according to FIG. 1,

FIG. 5 is a perspective view of the inventive bonding tool according to FIG. 1 with a representation of a laser beam impinging on the functional recess with a focused beam path,

FIG. 6 is a side view of the bonding tool with the laser beam according to FIG. 5,

FIG. 7 is a side view of the bonding tool with the laser beam with a collimated beam path,

FIG. 8 is a side view of the bonding tool with the laser beam with a divergent beam path,

FIG. 9 is a second embodiment of the inventive bonding tool in a front view,

FIG. 10 is the bonding tool according to FIG. 9 in a longitudinal side view,

FIG. 11 is the bonding tool according to FIG. 9 in a view of the underside and

FIG. 12 is a third embodiment of the bonding tool of the invention in a front view.

### DETAILED DESCRIPTION

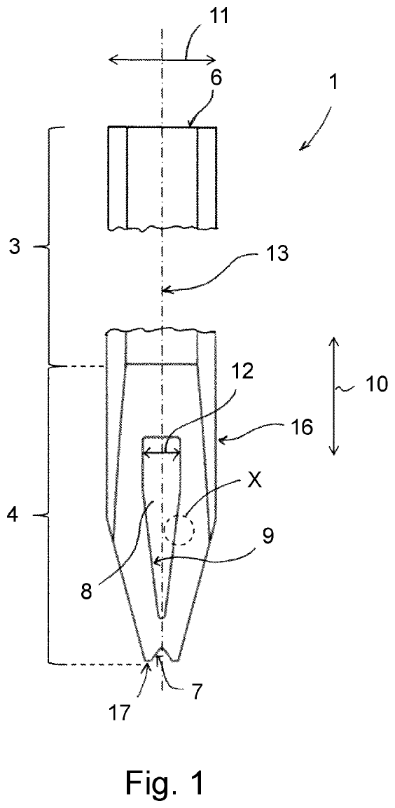

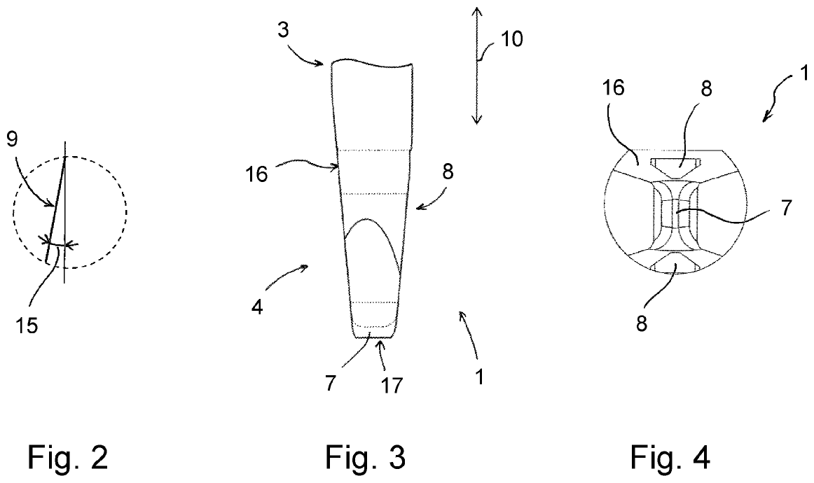

An inventive bonding tool according to FIGS. 1 to 4 provides a tool shank 3, which is extended in a longitudinal direction of the tool 10. Furthermore, the bonding tool 1 provides a tool tip 4 which connects to the tool shank 3. The tool tip 4 of the bonding tool 1 has a first end side 17. A second end side 6 is provided on the tool shank 3, opposite the first end side 17. The second end side 6 has a closed surface, i.e., is designed without a recess or opening. In the area of the second end side 6, the bonding tool 1 is held in receptacle of the bonding machine during bonding. In addition, the bonding tool 1 has a casing surface connecting the first end side 17 and the second end side 6.

On the first end side 17 is a receiving slot which extends transversely to the longitudinal direction of the tool 10. The receiving slot is designed to accommodate a bond wire, which serves as a connection part during bonding. In the area of the receiving slot, the bonding tool 1 comes into contact with the bond wire on the casing side when the bond connection is established with a bond contact surface 7.

In the area of the tool tip 4, moreover, a functional recess 8 is formed. The functional recess 8 is formed on the casing surface 16 of the bonding tool 1. The functional recess 8 is designed as a through recess. It is orthogonally oriented to the longitudinal direction of the tool 10.

The functional recess 8 has a constant width 12 in an area facing the second end side 6 or the tool shank 3 and then tapers wedge-shaped in the direction of the underside 17 of the tool tip 4. In the area of the wedge-shaped tapering, two opposing boundary surfaces 9 of the functional recess 8 are formed as absorption or deflection surfaces for a laser beam 2. The deflection surfaces 9 are flat and arranged inclined at an acute angle of attack 15 to the longitudinal direction of the tool 10.

In the present embodiment of the invention, a width 12 of the functional recess 8 orthogonally determined to the longitudinal direction of the tool 10 is in each case smaller than two thirds of a corresponding external width 11 of the bonding tool 1. Therefore, the bonding tool 1 always provides for sufficient material in the area of the functional recess 8 to ensure adequate mechanical stability.

In terms of a median longitudinal plane 13 of the bonding tool 1, the latter is symmetrically formed. The symmetry promotes the vibration properties of the bonding tool 1.

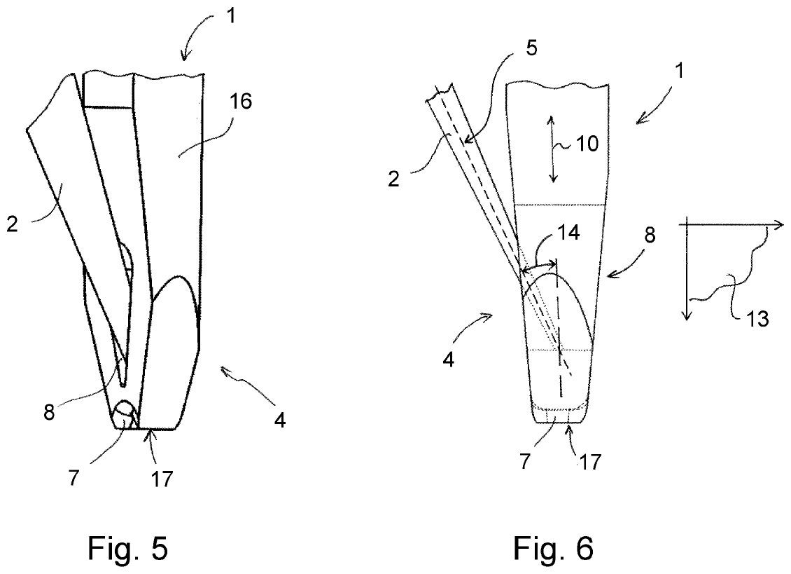

FIGS. 5 and 6 show the bonding tool 1, while the laser beam 2, which is provided by a laser generator of the inventive bonding arrangement impinges on the bonding tool 1 obliquely from above in the area of the functional recess 8. An acute angle of incidence of about 30° is formed between an incidence direction 5 of the laser beam 2 and the longitudinal direction of the bonding tool 10.

The laser beam 2, which is provided by the laser generator, is guided to the bonding tool via a light guide. While the laser generator is preferably arranged stationary, preferably at least a part of the light guide will be fixed to a movably held bonding head of the bonding machine serving the positioning of the bonding tool 1 and will be moved as well when positioning the bonding head. The light guide is distanced from the bonding tool 1 and associated with said bonding tool on the casing side from the outside and positioned such that the laser beam 2 coupled out via an end side of the light guide facing the functional recess impinges on the bonding tool 1 in the functional recess 8 and heats said bonding tool, in particular in the area of the tool tip 4.

The laser beam 2 is focused. For focusing the usually divergent laser beam 2 exiting the light guide, for example, a focusing lens or another suitable beam-forming optical unit is arranged in the beam path of the laser beam 2 between the light guide and the bonding tool 1.

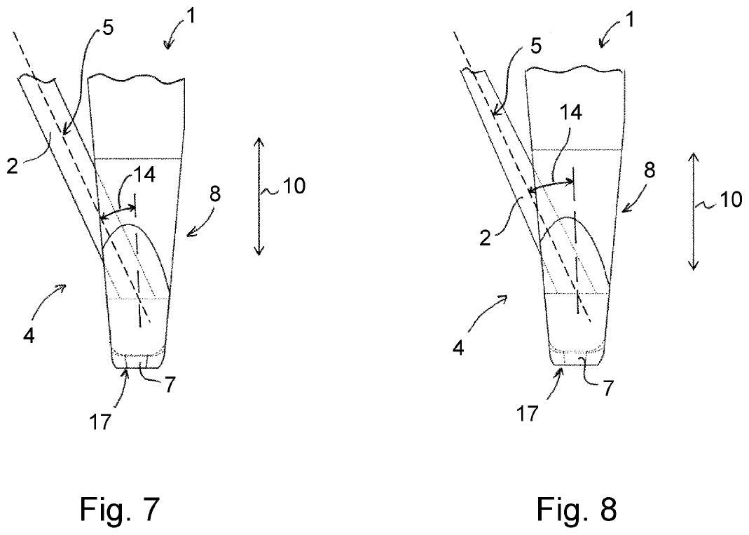

FIG. 7 shows a side view of the bonding arrangement according to the invention having the bonding tool 1 and the laser beam 2, which, as before, impinges on the bonding tool in the functional recess 8. The laser beam 2 has, in the present case, a collimated beam path, i.e., one which is directed at least approximately parallel. For this purpose, for example, a collimator optical unit is provided in the beam path of the laser beam.

In FIG. 8, a diverging laser beam 2 is provided by means of the bonding arrangement of the invention, which impinges on the bonding tool in the known manner in the functional recess 8. Since the laser beam 2 is usually coupled out divergently from the light guide of the bonding arrangement, a beam-forming optical unit in the beam path of the laser beam 2 can be dispensed with.

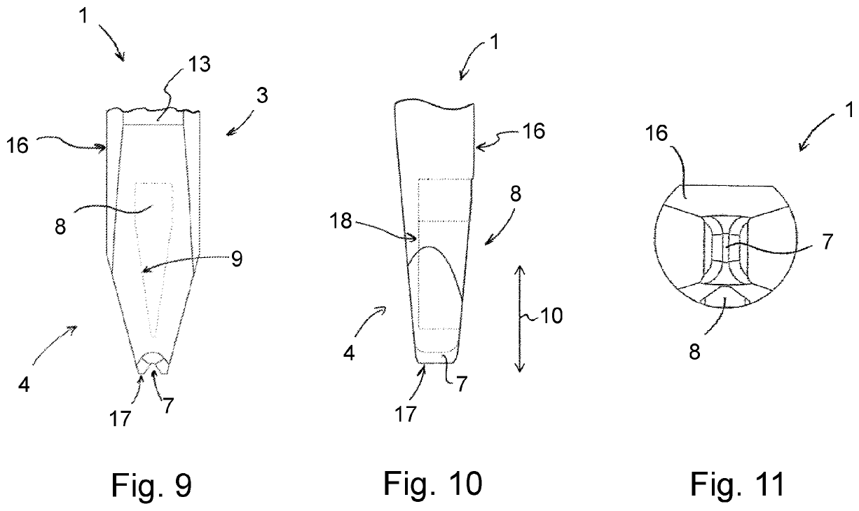

A first alternative embodiment of the inventive bonding arrangement is shown in FIGS. 9 to 11. In this case, the bonding tool has a congruently formed functional recess 8 that is now pocket or trough shaped. Thus, the functional recess 8 is not designed as a through recess. It is bordered on the front by a wall 18 and open to a back side. In this respect, the laser beam 2 will be directed from the back side into the functional recess 8. Otherwise, the bonding arrangement corresponds to the one discussed above.

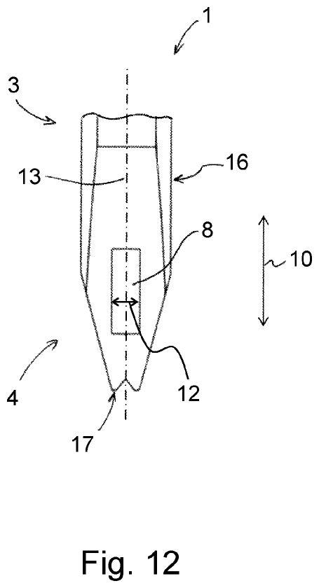

While according to the first two exemplary embodiments of the invention the functional recess 8 tapers wedge-shaped in the direction of the first end side 17 of the tool tip 4, the third embodiment of the invention shown in FIG. 12 has a functional recess 8 which is rectangular in cross-section, the width 12 being constant in the longitudinal direction of the tool 10. As before, the functional recess 8 is fully arranged in the area of the tool tip 4 and designed as a through recess. Of course, it may be provided here alternatively that the functional recess 8 is pocket-shaped.

The width 12 of the functional recess 8 may increase in sections in the direction of the underside 17. For example, the functional recess 8 can be cone-shaped or frustum-shaped. For example, the width 12 of the functional recess 8 may be determined in such a way that the laser beam does not impinge on the lateral boundary surfaces of the functional recess 8, but instead impinges on a lower boundary surface of the functional recess 8 which is associated with the first end side 17 of the bonding tool 1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A bonding arrangement comprising:
a bonding tool having a tool shank which is designed to extend in a longitudinal direction of the tool and having a tool tip which connects to the tool shank;
a first end side of the bonding tool provided on the tool tip, which is designed to come into contact with a connection part;
a second end side of the bonding tool provided on the tool shank, the bonding tool comprises a casing surface connecting the first end side and the second end side;
a laser generator to provide a laser beam;
a light guide to guide the laser beam to the bonding tool; and
a functional recess formed on the bonding tool on the casing side,
wherein the light guide is associated with the bonding tool on the casing side from an outside and at a distance such that the laser beam coupled out via an end side of the light guide facing the functional recess impinges on the bonding tool in the functional recess.

2. The bonding arrangement according to claim 1, wherein the functional recess is designed as a beam trap such that at least one boundary surface of the functional recess is formed as a deflection surface for the laser beam and has an angle of attack deviating by 0° and 90° to a direction of incidence of the laser beam and/or is curved.

3. The bonding arrangement according to claim 1, wherein the functional recess is at least partially formed on the tool tip (4).

4. The bonding arrangement according to claim 1, wherein the functional recess tapers towards the first end side and/or the first end side and/or the second end side are designed as a closed surface.

5. The bonding arrangement according to claim 1, wherein the functional recess is prepared by wire EDM and/or by die-sinking EDM and/or by additive manufacturing processes and/or by primary forming and/or machining.

6. The bonding arrangement according to claim 1, wherein the light guide comprises a glass fiber or a glass fiber bundle and/or that the light guide and/or the glass fiber (s) is coated with a reflection coating on the outside, at least in sections.

7. The bonding arrangement according to claim 1, wherein a width determined transversely to the longitudinal direction of the tool of the functional recess is always smaller than two thirds and preferably smaller than half of a corresponding width of the bonding tool.

8. The bonding arrangement according to claim 1, wherein the bonding tool with the functional recess is symmetrically formed to a median longitudinal plane of the bonding tool and/or wherein a cross-section of the functional recess is in any case constant in sections.

9. The bonding arrangement according to claim 1, wherein the functional recess is pocket-shaped.

10. The bonding arrangement according to claim 1, wherein the functional recess is designed as a through recess.

11. The bonding arrangement according to claim 1, wherein the width of the bonding tool in the area of the tool tip decreases in the direction of the first end side and/or wherein a bond contact surface is provided on the first end side for the connection part.

12. The bonding arrangement according to claim 1, wherein an ultrasonic generator is provided and that the ultrasonic generator interacts with the bonding tool in such a way that the bonding tool is excited to ultrasonic vibration or to ultrasonic bending vibration by the ultrasonic generator.

13. The bonding arrangement according to claim 1, wherein between the direction of incidence of the laser beam and the longitudinal direction of the tool an angle of incidence of a maximum of 90° and preferably of 60° or less and particularly preferably of 30° +/− 10° is formed.

14. A bonding tool for a bonding arrangement according to claim 1, the bonding tool comprising:
a tool shank which is designed to extend in a longitudinal direction of the tool; and
a tool tip that connects to the tool shank,
wherein a first end side of the bonding tool is provided on the tool tip, which is designed to come into contact with a connection part,
wherein a second end side of the bonding tool with a closed surface is provided on the tool shank,
wherein the bonding tool has a casing surface connecting the first end side and the second end side, and
wherein a functional recess is formed on the bonding tool on the casing side.

15. The bonding arrangement according to claim 1, wherein the bonding arrangement is provided for laser-supported ultrasonic bonding or for laser-supported ultrasonic wire bonding.
